(19) United States
(12) Patent Application Publication
(10) Pub. No.: US 2006/0132027 A1
(43) Pub. Date: Jun. 22, 2006

(54) Method and display element with reduced thermal stress

(76) Inventor: Zhanjun Gao, Rochester, NY (US)

Correspondence Address: Paul A. Leipold;Patent Legal Staff, Eastman Kodak Company, 343 State Street, Rochester, NY, 14650-2201, US

(21) Appl. No.: 11/021,132

(22) Filed: Dec. 22, 2004

(51) Int. Cl. H01J 1/62; H01J 63/04

(52) U.S. Cl. 313/506

(57) ABSTRACT

The invention relates to a flexible display device comprising properly selected layers so that the thermal stress in the display can be reduced to avoid failure. The flexible display comprises in order a substrate layer, a conductive layer, a flexible light-emitting layer, a conductive layer, and a superstrate layer wherein the display is balanced such that the layer most subject to damage by stress is substantially stress-free. In addition, the invention provides methods of constructing such a balanced flexible display.

### FIELD OF THE INVENTION

This invention relates in general to a display device, and more particularly to a flexible OLED display device comprising properly selected layers so that the thermal stress in the display can be reduced to avoid stress-induced damage or failure.

### BACKGROUND OF THE INVENTION

Most of commercial displays devices, for example, liquid crystal displays (LCD), or solid-state organic light-emitting diode (OLED) are rigid. LCD comprise two plane substrates, commonly fabricated by a rigid glass material, and a layer of a liquid crystal material or other imaging layer, and arranged in-between said substrates. The glass substrates are separated from each other by equally sized spacers being positioned between the substrates, thereby creating a more or less uniform gap between the substrates. Further, electrode means for creating an electric field over the liquid crystal material are provided and the substrate assembly is then placed between crossed polarizers to create a display. Thereby, optical changes in the liquid crystal display may be created by applying a voltage to the electrode means, whereby the optical properties of the liquid crystal material disposed between the electrodes is alterable.

In recent years, scientists and engineers have been enticed by the vision of flexible displays. A flexible display is defined in this disclosure as a flat-panel display using thin, flexible substrate, which can be bent to a radius of curvature of a few centimeters or less without loss of functionality. Flexible displays are considered to be more attractive than conventional rigid displays. They allow more freedom in designed, promise smaller and more rugged devices. On the other hands, under bending moments, the rigid display tends to lose its image over a large area, due to the fact that the gap between the substrates changes, thereby causing the liquid crystal material to flow away from the bending area, resulting in a changed crystal layer thickness. Consequently, displays utilizing glass substrates are less suitable, when a more flexible or even bendable display is desired.

Another advantage of using flexible substrates is that a plurality of display devices can be manufactured simultaneously by means of continuous web processing such as, for example, reel-to-reel processing. The manufacture of one or more display devices by laminating (large) substrates is alternatively possible. Dependent on the width of the reels used and the length and width of a reel of (substrate) material, a great many separate (display) cells or (in the case of “plastic electronics”) separate (semi-) products can be made in these processes. Such processes are therefore very attractive for bulk manufacture of said display devices and (semi-) products.

Some efforts have been made in the field of exchanging the above described glass substrates with substrates of a less fragile material, such as plastic. Plastic substrates provide for lighter and less fragile displays. One display using plastic substrates are described in the patent document U.S. Pat. No. 5,399,390. However, the natural flexibility of the plastic substrates presents problems, when trying to manufacture liquid crystal displays in a traditional manner. For example, the spacing between the substrates must be carefully monitored in order to provide a display with good picture reproduction. An aim in the production of prior art displays utilizing plastic substrate has therefore been to make the construction as rigid as possible, more or less imitating glass substrates. Thereby the flexible properties of the substrates have not been utilized to the full extent.

U.S. Pat. No. 6,710,841 discloses a liquid crystal display device having a first and a second substrate, being manufactured in a flexible material with a liquid crystal material is disposed between the substrates. Together, the substrates form an array of cell enclosures, each containing an amount of liquid crystal. Further, each of said cell enclosures is separated from the adjacent enclosures by intermediate flexible parts. By creating a display from a flexible material and subdividing the display into a plurality of separate cell enclosures, the flexible, bendable display will bend along an intermediate part rather than through a liquid crystal filled cell, thereby maintaining the display quality, since the cells or “pixels” of the display are left intact. U.S. Pat. No. 6,710,841 only applies to displays for which the display module is stiff and therefore, has a high bending stiffness in comparison with the substrate. However, as disclosed in EP 1403687 A2, some displays have nano-dimension conductive layer and display layer. For such display, the intermediate part has a similar bending stiffness in comparison with the liquid crystal enclosures. Therefore, the enclosures experience bending similar to the intermediate part. The flexibility of the display is limited by the bending limitation of the display enclosures. EP 1403687 A2 also calls for two substrates that sandwich the display enclosures in the middle.

WO 02/067329 discloses a flexible display device comprising a flexible substrate, a number of display pixels arranged in a form of rows and columns on the surface of the substrate, a number of grooves in the surface of the substrate, each of which is formed in between adjacent two rows or columns of the display pixels, and connection lines for electrically interconnecting the plurality of display pixels, thereby providing flexibility to the display device and, at the same time, minimizing the propagation of mechanical stress caused when the display device is bent or rolled. A method of manufacturing the display device is also disclosed. However, the introduction of grooves to the substrate causes significant stress concentration in the grooves. This may lead to substrate fracture during manufacturing or usage.

Solid-state organic light-emitting diode (OLED) image display devices utilize current passing through thin films of organic material to generate light. The color of light emitted and the efficiency of the energy conversion from current to light are determined by the composition of the organic thin-film material. Different organic materials emit different colors of light.

From a structural perspective, OLED and other flexible display devices are essentially a multilayer stack of thin film laminates. These laminates can range in thickness from a few nanometers, to hundreds of microns. When these structures carry an electrical current, joule heating takes place, and there is a potential for deleterious structural stress due to the mismatch of thermal expansion coefficients from one layer to the next. The prior art has attempted to address the aforementioned drawbacks and disadvantages, but has achieved mixed results.

For example, in order to redistribute thermal stress, the use of a spacer layer between the thin film and a more rigid layer of a multilayer flexible electronic device has been devised. Although this technique is applied in U.S. Pat. Nos. 6,281,452B1 and 6,678,949 in order to minimize thermal stress, it is nonetheless characterized by drawbacks. This method is generally less than ideal, since it adds unnecessary thickness to a device that is required to be sufficiently thin. Additionally, such thickness restrictions hinder the possibility of employing additional layers that may be needed to minimize thermal stress.

U.S. Pat. No. 5,319,479 discloses a multilayer device, comprised of an electronic element, a plastic substrate, and a thin film, wherein the thermal deformation of the thin film is minimized by plastic substrate and the electronic element. This method has a distinct disadvantage in that it does not provide flexibility in adjusting the coefficient of thermal expansion and the thickness of the respective layers.

Thus there remains a need for a more comprehensive method of eliminating thermally induced stress in multilayer flexible display devices.

### PROBLEM TO BE SOLVED BY THE INVENTION

This invention is to address the issues of thermal stress related method and display element that reduce the thermal stress in the display, more specifically in the layer most subject to damage by stress in the display.

### SUMMARY OF THE INVENTION

This invention relates to a flexible display comprising in order a substrate layer, a conductive layer, a flexible light-emitting layer, a conductive layer, and a superstrate layer, wherein the display is balanced such that the layer most subject to damage by stress is substantially stress-free.

### ADVANTAGEOUS EFFECT OF THE INVENTION

The invention provides a display device, and more particularly a flexible display device for which the stress in at least one layer of the light-emitting module in the display is substantially zero at the operating temperature. The layer can be chosen to be the most vulnerable layer in the light-emitting module to avoid stress-induced damage and failure of the display.

### BRIEF DESCRIPTION OF THE DRAWINGS

FIG. 1 represents a section view of one embodiment of the present invention.

FIG. 2 represents a section view of the embodiment in FIG. 1 under a temperature change. Stress is developed in each layer due to in-plane expansion. For example, a compressive stress is developed in the anode layer 40.

FIG. 3. When the display is under bending, there is a neutral axis along which no normal stress exists. On one side of the neutral axis, the material is under tension; while on the other side of the neutral axis, the material is under compression. The combined in-plane expansion and bending may, if designed correctly, results in essentially zero stress in the layer most subject to damage by stress in the display.

FIG. 4 represents a section view of a generic multi-layered material with the commonly used nomenclatures.

FIG. 5 represents a section view of another embodiment of the present invention where the substrate or superstrate or both have a predetermined curvature.

FIG. 6 represents a section view of yet another embodiment of the present invention.

FIG. 7 represents a section view of an example of the present invention.

FIG. 8. Curvature of the display under 20° C. degree temperature changes.

FIG. 9. Stress in indium tin oxide (ITO) conductive layer under 20° C. degree temperature change.

### DETAILED DESCRIPTION OF THE INVENTION

This invention relates in general to a display device, and more particularly to a flexible display device comprising display component layers and display substrate and superstrate with properly selected properties (modulus, coefficient of thermal and moisture expansion, as well as thermal shrinkage behavior), dimensions and initial curvatures. When such a flexible display reaches its designed steady state operating temperature, the stress in the layer most subject to damage by stress in the display is minimized.

These and other objects of the invention are accomplished by providing a flexible display comprising in order a substrate layer, a conductive layer, a flexible light-emitting layer, a conductive layer, and a superstrate layer wherein the display is balanced such that the layer most subject to damage by stress is substantially stress-free. Furthermore, the substrate or superstrate may have a predetermined curvature in such a way that when the device reaches a stead state operating temperature, layer most subject to damage by stress is substantially stress-free, and the display become essentially flat.

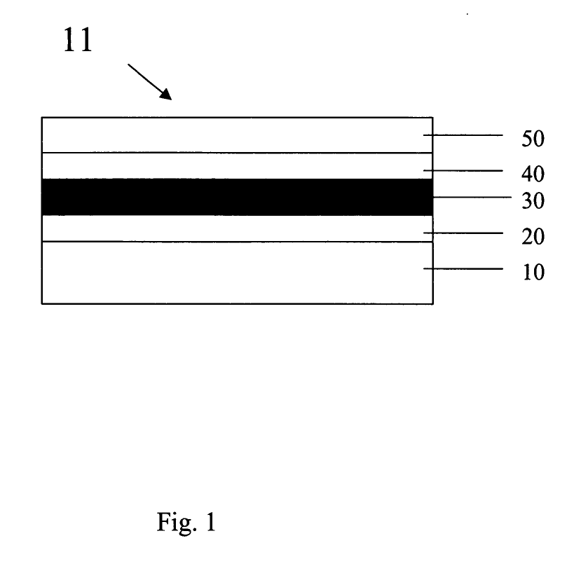

Referring to FIG. 1, one embodiment of the flexible display element 11 of the present invention includes a substrate 10, an anode 20, a light-emitting layer 30, and a cathode 40, and at least one superstrate 50. These layers are described in detail below. Note that the substrate may alternatively be located adjacent to the cathode, or the substrate may actually constitute the anode or cathode. The light-emitting layer may contain organic layers and other layers such as a hole-injecting layer, a hole-transporting layer, and electron-transporting layer. The total combined thickness of the organic layers is typically less than 500 nm as disclosed in U. S. Pat. No. 6,771,021.

Flexible displays are made of multilayered thin films. These film layers have different thickness, thermal expansion coefficients and thermal shrinkage behavior that results in deflection and bending stress due to temperature changes. The deflection and stress can affect the display quality as well failure of display components.

The present flexible display element consists display component and display support with properly selected properties (modulus, coefficient of thermal and moisture expansion, as well as thermal shrinkage behavior), dimensions and initial curvatures. When such a flexible display is utilized, the change of temperature causes the display to flatten. The in-plane stress and bending stress in layer most subject to damage by stress cancels each other out so that the layer most subject to damage by stress is stress free.

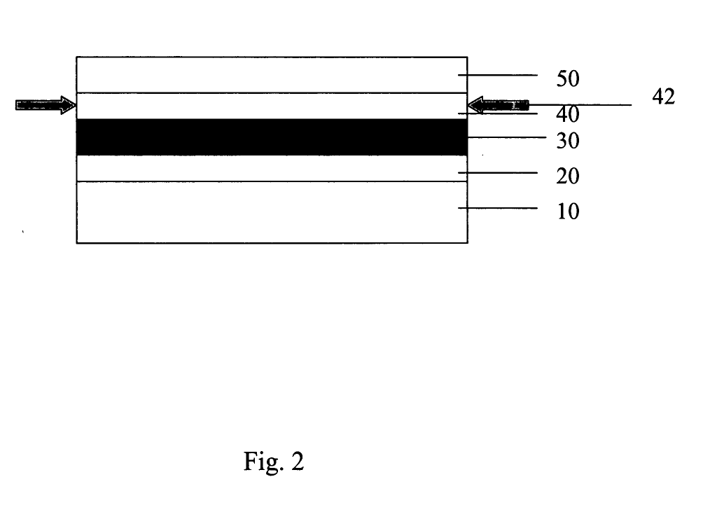

Referring to FIG. 1, anode layer 40 is considered the layer that is most subject to damage by stress since it can sustain very minimal stress before fracture. When the display 11 shown in FIG. 1 is under temperature change, since the layers in the display have different coefficient of thermal expansion, they tend to expansion differently. However, the layers are bonded together and the final expansion of the display is a compromised position where layers are under either compression or tension, depending on the values of the coefficients of thermal expansion. In FIG. 2, anode layer 40 is prevented from expansion longer than other layers in the display, and therefore, anode layer 40 is under in-plane compression as shown by arrow 42.

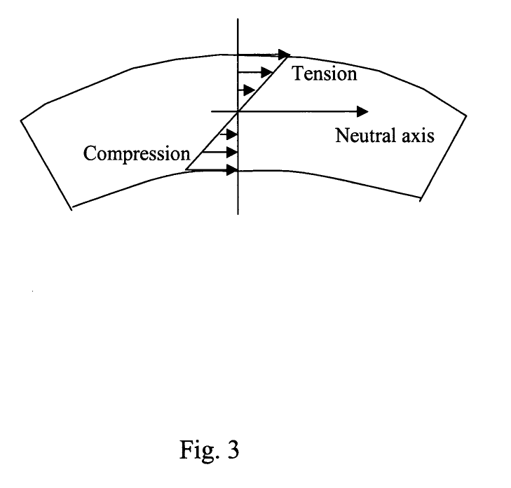

The thermal expansion of the display in FIG. 1 can also cause bending. In general, when a beam or plate is under bending, there exist a neutral axis along which the normal stress is zero. The beam or plate is under tension on one side of the neutral axis and compression on the other side. The total stress in the display 1 is the summation of the in-plane stress, FIG. 2, and the bending stress, FIG. 3. The present invention calls for display 1 that contains layers with desired properties (thickness, coefficient of thermal expansion, Young's modulus) so that the in-plane stress and bending stress in the layer most subject to damage by stress cancels each other out so that the layer most subject to damage by stress is stress free. Such a concept is explained in details using related mathematical formulation below.

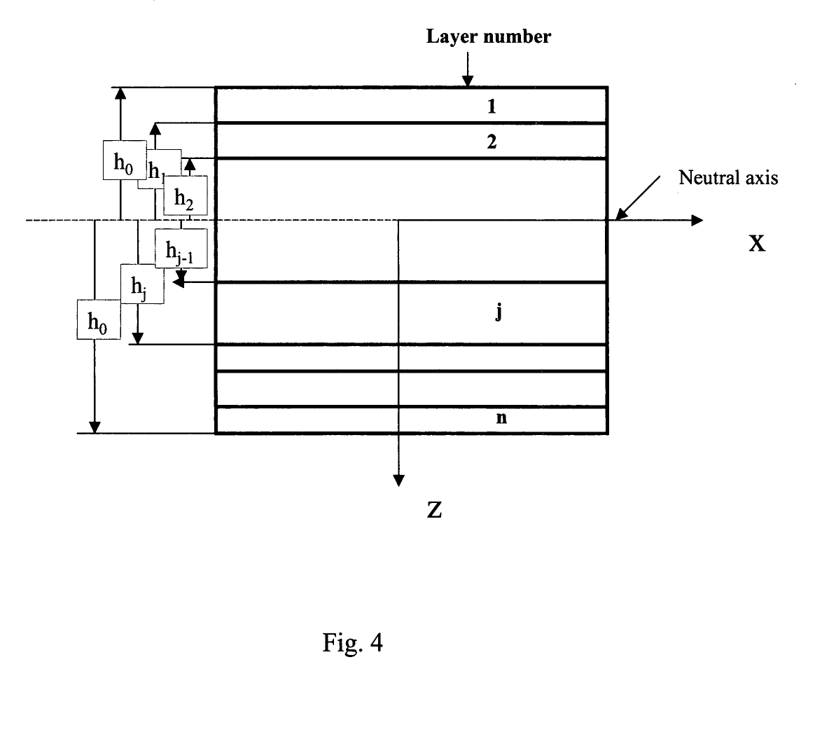

The stress in the laminates due to temperature change is denoted by {σ^{T}}. It is determined that the stress in the j-th layer of a n-layer display is given in the form below, see FIG. 4,

$${\{ \begin{matrix}{σ}_{x}^{T} \\ {σ}_{y}^{T} \\ {σ}_{xy}^{T}\end{matrix} \}}_{j} = [ Q ] [ \{ \begin{matrix}{ɛ}_{x}^{0} \\ {ɛ}_{y}^{0} \\ {ɛ}_{xy}^{0}\end{matrix} \} + {h}_{k} \{ \begin{matrix}{k}_{x} \\ {k}_{y} \\ {k}_{xy}\end{matrix} \} - Δ T {\{ \begin{matrix}{α}_{x} \\ {α}_{y} \\ {α}_{xy}\end{matrix} \}}_{j} ] \qquad ( 1 )$$

where
{σ^{T}}ⱼ=Thermal stress in the j-th layer in the n-layer laminate,
{ε⁰}=Mid-plane strain,
{k}=Plate curvature,
{α}ⱼ=Coefficients of thermal expansion in the j-th layer in the n-layer laminate,
ΔT=Temperature change,
[Q]=Material property matrix, and
hⱼ=Distance of the j-th layer to the neutral plane where the normal stress is zero.
The mid-plane strain and plate curvature are determined from the following equations

$$[ A ] \{ \begin{matrix}{ɛ}_{x}^{0} \\ {ɛ}_{y}^{0} \\ {ɛ}_{xy}^{0}\end{matrix} \} + [ B ] \{ \begin{matrix}{k}_{x} \\ {k}_{y} \\ {k}_{xy}\end{matrix} \} = \{ \begin{matrix}{N}_{x}^{T} \\ {N}_{y}^{T} \\ {N}_{xy}^{T}\end{matrix} \} \qquad ( 2 )$$

$$[ B ] \{ \begin{matrix}{ɛ}_{x}^{0} \\ {ɛ}_{y}^{0} \\ {ɛ}_{xy}^{0}\end{matrix} \} + [ D ] \{ \begin{matrix}{k}_{x} \\ {k}_{y} \\ {k}_{xy}\end{matrix} \} = \{ \begin{matrix}{M}_{x}^{T} \\ {M}_{y}^{T} \\ {M}_{xy}^{T}\end{matrix} \} \qquad ( 3 )$$

where [M^{T}] is the moments caused by temperature change, [N^{T}] is the in plane forces caused by temperature change, and

$$\{ \begin{matrix}{N}_{x}^{T} \\ {N}_{y}^{T} \\ {N}_{xy}^{T}\end{matrix} \} = Δ T {\sum }_{j = 1}^{n} {[ Q ]}_{j} {\{ \begin{matrix}{α}_{x} \\ {α}_{y} \\ {α}_{xy}\end{matrix} \}}_{j} ( {h}_{j} - {h}_{j - 1} ) \\ \{ \begin{matrix}{M}_{x}^{T} \\ {M}_{y}^{T} \\ {M}_{xy}^{T}\end{matrix} \} = \frac{1}{2} Δ T {\sum }_{j = 1}^{n} {[ Q ]}_{j} {\{ \begin{matrix}{α}_{x} \\ {α}_{y} \\ {α}_{xy}\end{matrix} \}}_{j} ( {h}_{j}^{2} - {h}_{j - 1}^{2} ) \qquad ( 4 )$$

The expressions of material property matrices, [Q], [A], [B] and [D] are given in detail in “Analysis and Performance of Fiber Composites” by B. D. Agarwal and L. J. Broutman, 2nd Edition, John Wiley & Sons, Inc., New York, 1990.

Equations (2) and (3) determine the mid-plane strain, {ε⁰}, and the plate curvature, {k} for known forces and moments due to temperature and moisture changes, [M^{T}], [N^{T}]. Equation (1) then yields the stress in any ply.

From Equations (2) and (3), we can solve for {ε⁰}, and the plate curvature, {k} as follows.

$$\{ \begin{matrix}{ɛ}_{x}^{0} \\ {ɛ}_{y}^{0} \\ {ɛ}_{xy}^{0}\end{matrix} \} + {[ A ]}^{- 1} [ B ] \{ \begin{matrix}{k}_{x} \\ {k}_{y} \\ {k}_{xy}\end{matrix} \} = {[ A ]}^{- 1} \{ \begin{matrix}{N}_{x}^{T} \\ {N}_{y}^{T} \\ {N}_{xy}^{T}\end{matrix} \} \qquad ( 5 )$$

$$\begin{matrix}\{ \begin{matrix}{ɛ}_{x}^{0} \\ {ɛ}_{y}^{0} \\ {ɛ}_{xy}^{0}\end{matrix} \} + {[ B ]}^{- 1} [ D ] \{ \begin{matrix}{k}_{x} \\ {k}_{y} \\ {k}_{xy}\end{matrix} \} = {[ B ]}^{- 1} \{ \begin{matrix}{M}_{x}^{T} \\ {M}_{y}^{T} \\ {M}_{xy}^{T}\end{matrix} \} & ( 6 ) \\ \{ \begin{matrix}{k}_{x} \\ {k}_{y} \\ {k}_{xy}\end{matrix} \} = \{ {[ A ]}^{- 1} [ B ] - {[ B ]}^{- 1} [ D ] \} \{ {[ A ]}^{- 1} \{ \begin{matrix}{N}_{x}^{T} \\ {N}_{y}^{T} \\ {N}_{xy}^{T}\end{matrix} \} - {[ B ]}^{- 1} \{ \begin{matrix}{M}_{x}^{T} \\ {M}_{y}^{T} \\ {M}_{xy}^{T}\end{matrix} \} \} \\ Similarly , & ( 7 ) \\ {[ B ]}^{- 1} [ A ] \{ \begin{matrix}{ɛ}_{x}^{0} \\ {ɛ}_{y}^{0} \\ {ɛ}_{xy}^{0}\end{matrix} \} + \{ \begin{matrix}{k}_{x} \\ {k}_{y} \\ {k}_{xy}\end{matrix} \} = {[ B ]}^{- 1} \{ \begin{matrix}{N}_{x}^{T} \\ {N}_{y}^{T} \\ {N}_{xy}^{T}\end{matrix} \} & ( 8 ) \\ {[ D ]}^{- 1} [ B ] \{ \begin{matrix}{ɛ}_{x}^{0} \\ {ɛ}_{y}^{0} \\ {ɛ}_{xy}^{0}\end{matrix} \} + \{ \begin{matrix}{k}_{x} \\ {k}_{y} \\ {k}_{xy}\end{matrix} \} = {[ D ]}^{- 1} \{ \begin{matrix}{M}_{x}^{T} \\ {M}_{y}^{T} \\ {M}_{xy}^{T}\end{matrix} \} & ( 9 ) \\ \{ \begin{matrix}{ɛ}_{x}^{0} \\ {ɛ}_{y}^{0} \\ {ɛ}_{xy}^{0}\end{matrix} \} = {\{ {[ B ]}^{- 1} [ A ] - {[ D ]}^{- 1} [ B ] \}}^{- 1} \{ {[ B ]}^{- 1} \{ \begin{matrix}{N}_{x}^{T} \\ {N}_{y}^{T} \\ {N}_{xy}^{T}\end{matrix} \} - {[ D ]}^{- 1} \{ \begin{matrix}{M}_{x}^{T} \\ {M}_{y}^{T} \\ {M}_{xy}^{T}\end{matrix} \} \} & ( 10 )\end{matrix}$$

Finally, the stress in the j-th layer is given as

$${\{ \begin{matrix}{σ}_{x}^{T} \\ {σ}_{y}^{T} \\ {σ}_{xy}^{T}\end{matrix} \}}_{j} = [ Q ] [ \{ \begin{matrix}{ɛ}_{x}^{0} \\ {ɛ}_{y}^{0} \\ {ɛ}_{xy}^{0}\end{matrix} \} + {h}_{j} \{ \begin{matrix}{k}_{x} \\ {k}_{y} \\ {k}_{xy}\end{matrix} \} - Δ T {\{ \begin{matrix}{α}_{x} \\ {α}_{y} \\ {α}_{xy}\end{matrix} \}}_{j} ] = 0 \qquad ( 11 )$$

where {ε⁰},{k} are given in Equations (7) and (10). In Equation (11), the term

$$[ Q ] [ \{ \begin{matrix}{ɛ}_{x}^{0} \\ {ɛ}_{y}^{0} \\ {ɛ}_{xy}^{0}\end{matrix} \} - Δ T {\{ \begin{matrix}{α}_{x} \\ {α}_{y} \\ {α}_{xy}\end{matrix} \}}_{j} ]$$

represents the in-plane stress, while the term

$$[ Q ] [ {h}_{j} \{ \begin{matrix}{k}_{x} \\ {k}_{y} \\ {k}_{xy}\end{matrix} \} ]$$

represents the bending stress.

It is clear from Equations (7), (10) and (11) that the stress components (normal and shear) in each layer are uniquely determined from the properties (modulus, coefficient of thermal expansion), dimension and temperature change. Therefore, we can optimize or reduce the stress or certain stress components in the layer most subject to damage by stress so that stress-induced damage or failure will not occur. The layer most subject to damage by stress may include key layers such as conductive layer. For example, to minimize the stress in the j-th layer which is critical layer, we need to select the properties (modulus, thickness, coefficient of thermal expansion) of individual layers so that so that condition (11) is satisfied. Actual examples are included below.

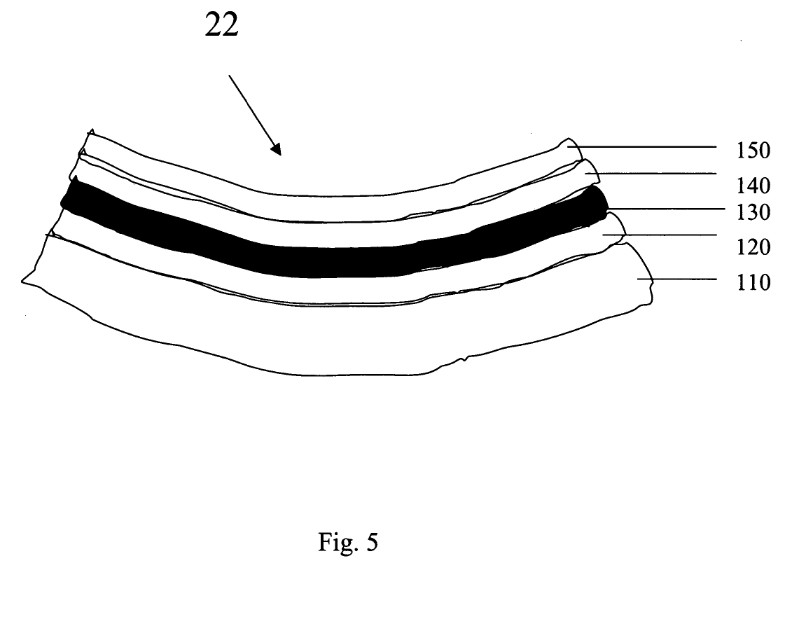

Another embodiment is shown in FIG. 5, where display 22 has a predetermined curvature that will become flat after temperature change ΔT. The predetermined curvature is equal to the curvature determined from equation (7), but in the opposite direction so that the curvature due to the temperature change cancels out the pre-existed curvature in the display 22. Therefore, the display is flat at the temperature change. In this embodiment, the substrate 110 and superstrate 150 have the predetermined curvature as a free standing substrate/superstrate.

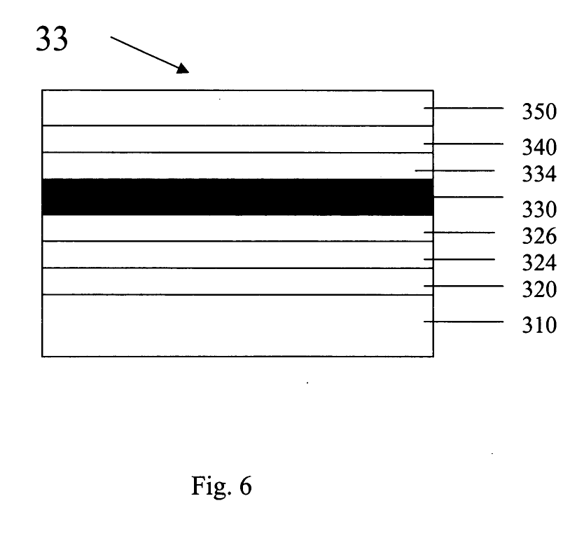

Another embodiment 33 is shown in FIG. 6 and is comprised of a substrate 310, an anode 320, a hole-injecting layer 324, a hole-transporting layer 326, a light-emitting layer 330, an electron-transporting layer 334, a cathode 340, and at least one top superstrate. These layers are described in detail below. Note that the substrate may alternatively be located adjacent to the cathode, or the substrate may actually constitute the anode or cathode. The organic layers between the anode and cathode are conveniently referred to as the organic EL element. The total combined thickness of the organic layers is preferably less than 500 nm.

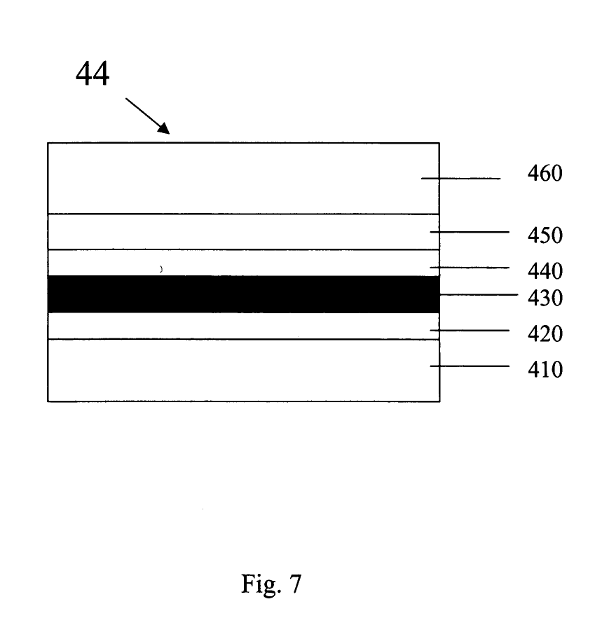

One example of an embodiment of the display structure is illustrated in FIG. 7. The layers shown in display 44 comprise aluminum substrate layer 410, cathod layer 420, imaging layer zone 430, anode layer 440, and transparent superstrate glass layer 450. Transparent superstrate glass layer 450 may also serve as an oxygen and moisture diffusion barrier in certain types of display devices. A thermal control layer 460 comprised of PET polymer has been incorporated on top of layer 450.

In the example studied, aluminum substrate layer 410 has a thickness of 500 μm, a thermal coefficient of expansion of 23×10⁻⁶/C and a Young's Modulus of 70 GPa. Glass layer 450 has a thickness of 60 μm, a thermal coefficient of expansion of 7×10⁻⁶/C, and a Young's Modulus of 50 GPa. Polymer superstrate PET layer 260 has a thermal coefficient of expansion of 70×10⁻⁶/C and a Young's Modulus of 4 GPa. The light-emitting layer 430 is 2 μm thick, the anode layer 440 and cathode layer 420 are 0.1 μm thick. The light-emitting layer 430, anode layer 440 and cathode layer 420 are much thinner and more flexible than the other layers and do not control thermal deformation in the overall device, but its properties does affect the stress in these layer. For the purposes of this example, it is assumed that the device experiences an overall temperature increase of 20° C. at equilibrium when operated. The anode layer 440 is made ITO which has a thermal coefficient of expansion of 7×10⁻⁵/C, and a Young's modulus of 4 GPa.

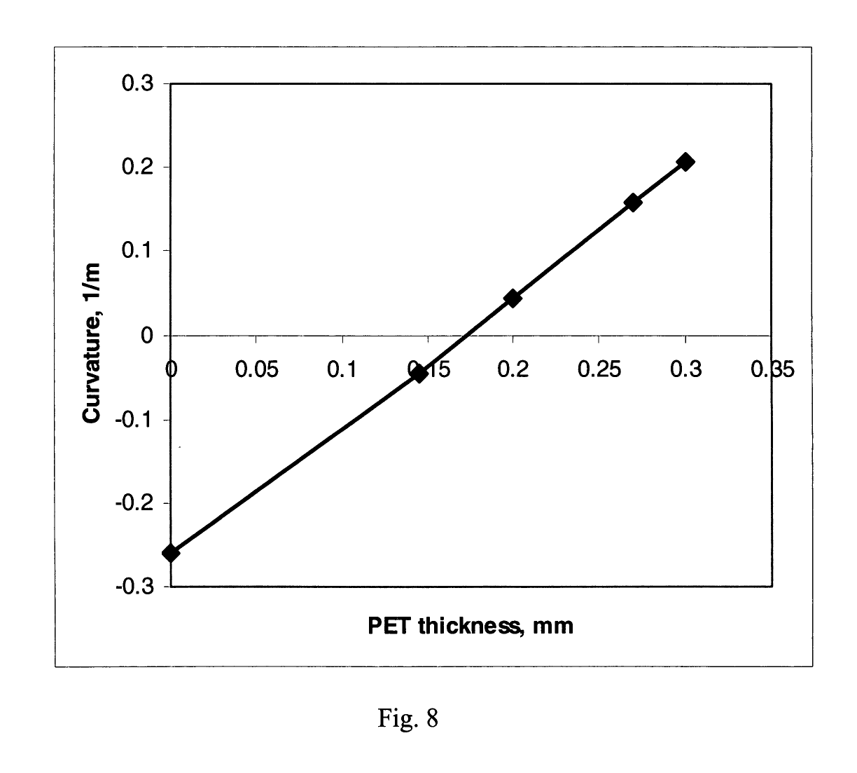

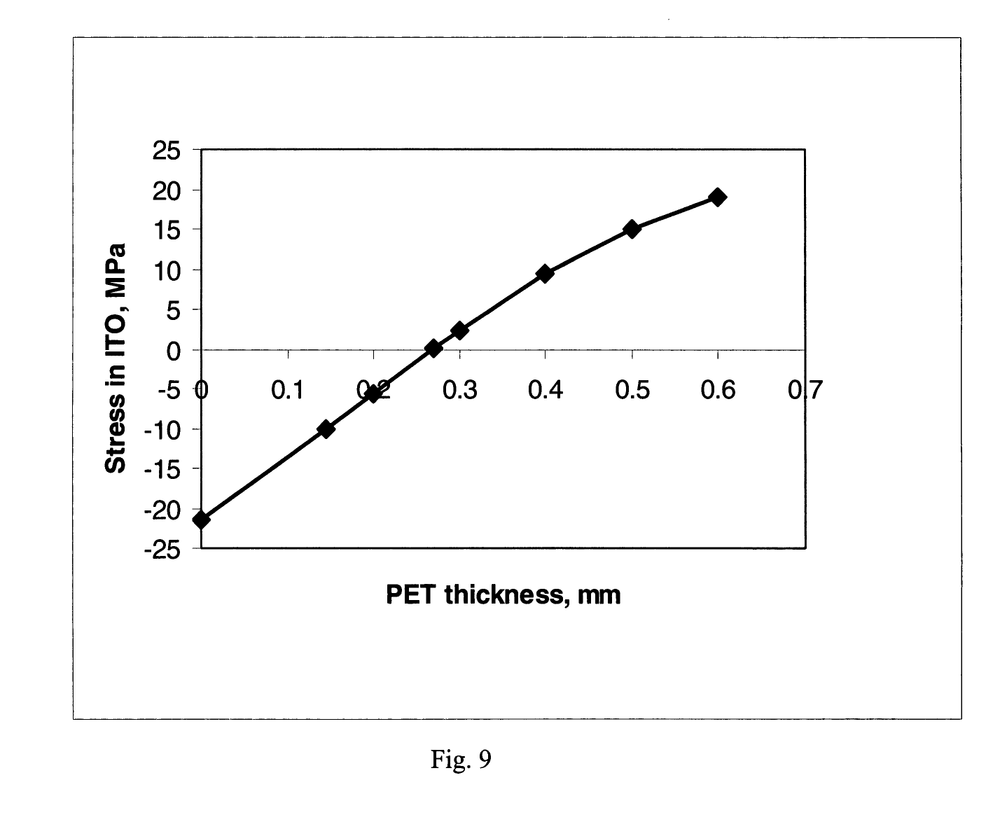

For this example, the effect of varying the thickness of the PET polymer layer 460 was modeled in accord with equations (1)-(11). It can be seen from FIG. 8 that the laminated structure 4 with a PET layer 460 of approximately 0.17 mm thickness will experience zero peak curvature. However, the stress in the anode layer 440 is equal to 10 MPa (not zero) when the thickness of the PET layer 460 is 0.17 mm. Such a stress level is rather high for ITO material as the anode layer 320. In fact, the stress in the ITO layer is zero when the thickness of the PET layer 460 is chosen as 0.27 mm, FIG. 9. At such a configuration, the curvature of the display under a temperature change of 20 C is 0.16 (1/m), FIG. 8. Therefore, one preferred embodiment of the present invention is to choose the thickness of the PET layer 460 as 0.27 mm so that the ITO layer 320 is stress free under a temperature change of 20 C when the display reaches its operating temperature. The display will experience a slight curvature (0.16 (1 /m)). Another preferred embodiment of the present invention is to select substrate 410, top substrates 450 and 460 in such a way so that they have a negative curvature of 0.16 (1 /m). In this case, the display 4 will be flat under the temperature change of 20 C when it reaches its operating temperature. Of course, the stress in the ITO layer is still zero.

The present invention can be employed in most OLED device configurations. These include very simple structures comprising a single anode and cathode to more complex devices, such as passive matrix displays comprised of orthogonal arrays of anodes and cathodes to form light-emitting elements, and active-matrix displays where each light-emitting element is controlled independently, for example, with thin film transistors (TFTs).

The anode and cathode of the OLED are connected to a voltage/current source through electrical conductors. The OLED is operated by applying a potential between the anode and cathode such that the anode is at a more positive potential than the cathode. Holes are injected into the organic EL element from the anode and electrons are injected into the organic EL element at the anode. Enhanced device stability can sometimes be achieved when the OLED is operated in an AC mode where, for some time period in the cycle, the potential bias is reversed and no current flows. An example of an AC-driven OLED is described in U.S. Pat. No. 5,552,678.

Substrate and Superstrate

The flexible display device of this invention is typically provided over a supporting substrate 310, FIG. 6, where either the cathode or anode can be in contact with the substrate. The electrode in contact with the substrate is conveniently referred to as the bottom electrode. Conventionally, the bottom electrode is the cathod, but this invention is not limited to that configuration. The substrate 10 can either be transmissive or opaque. In the case wherein the substrate is transmissive, a reflective or light absorbing layer is used to reflect the light through the cover or to absorb the light, thereby improving the contrast of the display. The superstrate 350, FIG. 6, is utilized to protect the light-emitting module and to balance the thermal expansion of the display. The superstrate should be transmissive. In general both substrate and superstrate can consist multiple materials in multiple layers. The substrate can be thin metal material (such as aluminum foil), flexible plastic film or combination of them. The superstrate can be any flexible self-supporting plastic film that supports the thin conductive metallic film. “Plastic” as a whole or a layer of the substrate 310 or superstrate 350 means a high polymer, usually made from polymeric synthetic resins, which may be combined with other ingredients, such as curatives, fillers, reinforcing agents, colorants, and plasticizers. Plastic includes thermoplastic materials and thermosetting materials.

The flexible plastic film must have sufficient thickness and mechanical integrity so as to be self-supporting, yet should not be so thick as to be rigid. Typically, the flexible plastic film is the thickest layer of the composite film in thickness. Consequently, the film determines to a large extent the mechanical and thermal stability of the fully structured composite film.

Another significant characteristic of the flexible plastic film material is its glass transition temperature (Tg). Tg is defined as the glass transition temperature at which plastic material will change from the glassy state to the rubbery state. It may comprise a range before the material may actually flow. Suitable materials for the flexible plastic film include thermoplastics of a relatively low glass transition temperature, for example up to 150° C., as well as materials of a higher glass transition temperature, for example, above 150° C. The choice of material for the flexible plastic film would depend on factors such as manufacturing process conditions, such as deposition temperature, and annealing temperature, as well as post-manufacturing conditions such as in a process line of a displays manufacturer. Certain of the plastic films discussed below can withstand higher processing temperatures of up to at least about 200° C., some up to 3000-350° C., without damage.

Typically, the flexible plastic film is polyethylene terephthalate (PET), polyethylene naphthalate (PEN), polyethersulfone (PES), polycarbonate (PC), polysulfone, a phenolic resin, an epoxy resin, polyester, polyimide, polyetherester, polyetheramide, cellulose acetate, aliphatic polyurethanes, polyacrylonitrile, polytetrafluoroethylenes, polyvinylidene fluorides, poly(methyl (x-methacrylates), an aliphatic or cyclic polyolefin, polyarylate (PAR), polyetherimide (PEI), polyethersulphone (PES), polyimide (PI), Teflon poly(perfluoro-alboxy) fluoropolymer (PFA), poly(ether ether ketone) (PEEK), poly(ether ketone) (PEK), poly(ethylene tetrafluoroethylene)fluoropolymer (PETFE), and poly(methyl methacrylate) and various acrylate/methacrylate copolymers (PMMA). Aliphatic polyolefins may include high density polyethylene (HDPE), low density polyethylene (LDPE), and polypropylene, including oriented polypropylene (OPP). Cyclic polyolefins may include poly(bis(cyclopentadiene)). A preferred flexible plastic film is a cyclic polyolefin or a polyester. Various cyclic polyolefins are suitable for the flexible plastic film. Examples include Arton® made by Japan Synthetic Rubber Co., Tokyo, Japan; Zeanor T made by Zeon Chemicals L.P., Tokyo Japan; and Topas® made by Celanese A. G., Kronberg Germany. Arton is a poly(bis(cyclopentadiene)) condensate that is a film of a polymer. Alternatively, the flexible plastic film can be a polyester. A preferred polyester is an aromatic polyester such as Arylite. Although various examples of plastic films are set forth above, it should be appreciated that the film can also be formed from other materials such as glass and quartz.

The flexible plastic film can be reinforced with a hard coating. Typically, the hard coating is an acrylic coating. Such a hard coating typically has a thickness of from 1 to 15 microns, preferably from 2 to 4 microns and can be provided by free radical polymerization, initiated either thermally or by ultraviolet radiation, of an appropriate polymerizable material. Depending on the film, different hard coatings can be used. When the film is polyester or Arton, a particularly preferred hard coating is the coating known as “Lintec.” Lintec contains UV-cured polyester acrylate and colloidal silica. When deposited on Arton, it has a surface composition of 35 atom % C, 45 atom % 0, and 20 atom % Si, excluding hydrogen. Another particularly preferred hard coating is the acrylic coating sold under the trademark “Terrapin” by Tekra Corporation, New Berlin, Wisconsin.

Hole-Injecting Layer (HIL)

While not always necessary, it is often useful to provide a hole-injecting layer 324 between anode 320 and hole-transporting layer 326. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl) phenylamino]triphenylamine). Alternative hole-injecting materials reportedly useful in organic EL devices are described in EP 0 891 121 A1 and EP 1 029 909 A1.

Hole-Transporting Layer (HTL)

The hole-transporting layer 326 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The hole-transporting layer can be formed of a single or a mixture of aromatic tertiary amine compounds. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
4,4′-Bis(diphenylamino)quadriphenyl
Bis(4-dimethylamino-2-methylphenyl)-phenylmethane
N,N,N-Tri(p-tolyl)amine
4-(di-p-tolylamino)-4′-[4(di-p-tolylamino)-styryl] stilbene
N,N,N′,N′-Tetra-p-tolyl-4-4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl
4,4′-Bis[N-(1-naphthyl)-N-(2-naphthyl)amino]biphenyl
4,4″-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4″-Bis[N-(l -anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis {N-phenyl-N-[4-(1-naphthyl)-phenyl]amino} biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4″-tris[(3-methylphenyl)phenylamino]triphenylamine

Another class of useful hole-transporting materials includes polycyclic aromatic compounds as described in EP 1 009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

As more fully described in U.S. Pat. Nos. 4,769,292 and 5,935,721, the light-emitting layer (LEL) 330 of the organic EL element includes a luminescent or fluorescent material where electroluminescence is produced as a result of electron-hole pair recombination in this region. The light-emitting layer can be comprised of a single material, but more commonly consists of a host material doped with a guest compound or compounds where light emission comes primarily from the dopant and can be of any color. The host materials in the light-emitting layer can be an electron-transporting material, as defined below, a hole-transporting material, as defined above, or another material or combination of materials that support hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material. Polymeric materials such as polyfluorenes and polyvinylarylenes (e.g., poly(p-phenylenevinylene), PPV) can also be used as the host material. In this case, small molecule dopants can be molecularly dispersed into the polymeric host, or the dopant could be added by copolymerizing a minor constituent into the host polymer.

An important relationship for choosing a dye as a dopant is a comparison of the bandgap potential which is defined as the energy difference between the highest occupied molecular orbital and the lowest unoccupied molecular orbital of the molecule. For efficient energy transfer from the host to the dopant molecule, a necessary condition is that the band gap of the dopant is smaller than that of the host material. For phosphorescent emitters it is also important that the host triplet energy level of the host be high enough to enable energy transfer from host to dopant.

Host and emitting molecules known to be of use include, but are not limited to, those disclosed in U.S. Pat. Nos. 4,768,292; 5,141,671; 5,150,006; 5,151,629; 5,405,709; 5,484,922; 5,593,788; 5,645,948; 5,683,823; 5,755,999; 5,928,802; 5,935,720; 5,935,721; and 6,020,078.

Metal complexes of 8-hydroxyquinoline (oxine) and similar derivatives constitute one class of useful host compounds capable of supporting electroluminescence. Illustrative of useful chelated oxinoid compounds are the following:
CO-1: Aluminum trisoxine [alias, tris(8-quinolinolato) aluminum(III)]
CO-2: Magnesium bisoxine [alias, bis(8-quinolinolato) magnesium(II)]
CO-3: Bis[benzo{f}-8-quinolinolato]zinc (II)
CO-4: Bis(2-methyl-8-quinolinolato)aluminum(III)-□-oxo-bis(2-methyl-8-quinolinolato) aluminum(III)
CO-5: Indium trisoxine [alias, tris(8-quinolinolato) indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato) gallium(III)]
CO-9: Zirconium oxine [alias, tetra(8-quinolinolato) zirconium(IV)]

Other classes of useful host materials include, but are not limited to: derivatives of anthracene, such as 9,10-di-(2-naphthyl) anthracene and derivatives thereof as described in U.S. Pat. No. 5,935,721, distyrylarylene derivatives as described in U.S. Pat. No. 5,121,029, and benzazole derivatives, for example, 2,2′,2″-(1,3,5-phenylene)tris[1-phenyl-1H-benzimidazole]. Carbazole derivatives are particularly useful hosts for phosphorescent emitters.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl) methane compounds, and carbostyryl compounds.

Electron-Transporting Layer (ETL)

Preferred thin film-forming materials for use in forming the electron-transporting layer 334 of the organic EL elements of this invention are metal chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

Cathode

When light emission is viewed solely through the anode, the cathode 313 used in this invention can be comprised of nearly any conductive material. Desirable materials have good film-forming properties to ensure good contact with the underlying organic layer, promote electron injection at low voltage, and have good stability. Useful cathode materials often contain a low work fimction metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin electron-injection layer (EIL) in contact with the organic layer (e.g., ETL) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of A1 as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,393. Cathode materials are typically deposited by evaporation, sputtering, or chemical vapor deposition. When needed, patterning can be achieved through many well known methods including, but not limited to, through-mask deposition, integral shadow masking, for example, as described in U.S. Pat. No. 5,276,380 and EP 0 732 868, laser ablation, and selective chemical vapor deposition.

Other Common Organic Layers and Device Architecture

In some instances, layers 326 and 334 can optionally be collapsed into a single layer that serves the finction of supporting both light emission and electron transportation. It also known in the art that emitting dopants may be added to the hole-transporting layer, which may serve as a host. Multiple dopants may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, U.S. Pat. No. 20020025419, EP 1 182 244, U.S. Pat. No. 5,683,823, U.S. Pat. No. 5,503,910, U.S. Pat. No. 5,405,709, and U.S. Pat. No. 5,283,182.

Additional layers such as electron or hole-blocking layers as taught in the art may be employed in devices of this invention. Hole-blocking layers are commonly used to improve efficiency of phosphorescent emitter devices, for example, as in U.S. Pat. No. 20020015859.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited through a vapor-phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,688,551, 5,851,709 and 6,066,357) and inkjet method (U.S. Pat. No. 6,066,357).

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters over the display. Filters, polarizers, and anti-glare or anti-reflection coatings may be specifically provided over the cover or an electrode protection layer beneath the cover.

The invention has been described in detail with particular reference to certain preferred embodiments thereof, but it will be understood that variations and modifications can be effected within the spirit and scope of the invention.

1. A flexible display comprising in order
a substrate layer,
a conductive layer,
a flexible light-emitting layer,
a conductive layer, and
a superstrate layer
wherein the display is balanced such that the layer most subject to damage by stress is substantially stress-free.

2. The flexible display of claim 1 wherein the flexible light-emitting layer is an organic light-emitting diode.

3. The flexible display of claim 1 wherein at least one of said conductive layers comprises indium tin oxide.

4. The flexible display of claim 1 wherein at least one of said substrates has a thickness of between 0.1 mm and 4 mm.

5. The flexible display of claim 1 wherein at least one of said substrates comprises a polymer layer, a glass layer, or a metal layer.

6. The flexible display of claim 1 wherein said light-emitting layer has a thickness of between 0.1 and 20 micrometers.

7. The flexible display of claim 1 wherein said layer most subject to damage by stress is one of the conductive layers.

8. The flexible display of claim 3 wherein said layer most subject to damage by stress is said indium tin oxide conductive layer.

9. The flexible display of claim 2 wherein said layer most subject to damage by stress is said flexible light-emitting layer.

10. The flexible display of claim 2 wherein said layer most subject to damage by stress is said organic light-emitting diode.

11. A flexible display comprising in order
a substrate layer,
a conductive layer,
a flexible light-emitting layer,
a conductive layer, and
a superstrate layer
wherein at least one of the substrate or superstrate has a predetermined curvature such that when the device reaches a stead state operating temperature, the layer most subject to damage by stress is substantially stress-free, and the display become essentially flat.

12. The flexible display of claim 11 wherein said flexible light-emitting layer is an organic light-emitting diode.

13. The flexible display of claim 11 wherein at least one of said conductive layers comprises indium tin oxide.

14. The flexible display of claim 11 wherein at least one of said substrataes has a thickness of between 0.1 mm and 4 mm.

15. The flexible display of claim 11 wherein at least one of said substrates comprises a polymer layer, a glass layer, or a metal layer.

16. The flexible display of claim 11 wherein said light-emitting layer has a thickness of between 0.1 and 20 micrometers.

17. The flexible display of claim 11 wherein said layer most subject to damage by stress is one of the conductive layers.

18. The flexible display of claim 13 wherein said layer most subject to damage by stress is said indium tin oxide conductive layer.

19. The flexible display of claim 11 wherein said layer most subject to damage by stress is said flexible light-emitting layer.

20. The flexible display of claim 12 wherein said layer most subject to damage by stress is said organic light-emitting diode.

21. A method of providing flexible display comprising:
determining the layer most subject to damage by stress in the flexible display comprising in order
a substitute layer,
a conductive layer,
a flexible light-emitting layer,
a conductive layer, and
a superstrate layer,
determining the stead state operating temperature of the display, and
selecting the materials for each layer with their thickness, Young's moduli, Poisson's ratios, coefficients of thermal expansion so that the said layer most subject to damage by stress (the j-th layer) satisfies Equation (11) and therefore, is stress-free, wherein Equation (11) is given as
$${\{ \begin{matrix}{σ}_{x}^{T} \\ {σ}_{y}^{T} \\ {σ}_{xy}^{T}\end{matrix} \}}_{j} = [ Q ] [ \{ \begin{matrix}{ɛ}_{x}^{0} \\ {ɛ}_{y}^{0} \\ {ɛ}_{xy}^{0}\end{matrix} \} + {h}_{j} \{ \begin{matrix}{k}_{x} \\ {k}_{y} \\ {k}_{xy}\end{matrix} \} - Δ T {\{ \begin{matrix}{α}_{x} \\ {α}_{y} \\ {α}_{xy}\end{matrix} \}}_{j} ] = 0 \qquad ( 11 )$$

22. The method in claim 21 wherein the flexible light-emitting layer is an organic light-emitting diode.

23. The method in claim 21 wherein at least one of said conductive layers comprises indium tin oxide.

24. A method of providing flexible display comprising in order
a substitute layer,
a conductive layer,
a flexible light-emitting layer,
a conductive layer, and
a superstrate layer
determining the stead state operating temperature of the display,
selecting the materials for each layer with their thickness, Young's moduli, Poisson's ratios, coefficients of thermal expansion so that the said layer most subject to damage by stress (the j-th layer) satisfies Equation (11) and therefore, is stress-free, wherein Equation (11) is given as
$${\{ \begin{matrix}{σ}_{x}^{T} \\ {σ}_{y}^{T} \\ {σ}_{xy}^{T}\end{matrix} \}}_{j} = [ Q ] [ \{ \begin{matrix}{ɛ}_{x}^{0} \\ {ɛ}_{y}^{0} \\ {ɛ}_{xy}^{0}\end{matrix} \} + {h}_{j} \{ \begin{matrix}{k}_{x} \\ {k}_{y} \\ {k}_{xy}\end{matrix} \} - Δ T {\{ \begin{matrix}{α}_{x} \\ {α}_{y} \\ {α}_{xy}\end{matrix} \}}_{j} ] = 0 \qquad ( 11 )$$
selecting said substrate and said superstrate with pre-existing curvature given in Equation (7)
$$\{ \begin{matrix}{k}_{x} \\ {k}_{y} \\ {k}_{xy}\end{matrix} \} = \{ {[ A ]}^{- 1} [ B ] - {[ B ]}^{- 1} [ D ] \} \{ {[ A ]}^{- 1} \{ \begin{matrix}{N}_{x}^{T} \\ {N}_{y}^{T} \\ {N}_{xy}^{T}\end{matrix} \} - {[ B ]}^{- 1} \{ \begin{matrix}{M}_{x}^{T} \\ {M}_{y}^{T} \\ {M}_{xy}^{T}\end{matrix} \} \} \qquad ( 7 )$$
but in opposite direction so that said display is balanced in such a way that the layer most subject to damage by stress has essentially no stress, and the said display become essentially flat when the device reaches a stead state operating temperature.

25. The method claimed in claim 24 wherein said flexible light-emitting layer is an organic light-emitting diode.

26. The method claimed in claim 24 wherein at least one of said conductive layers comprises indium tin oxide.

27. The method claimed in claim 24 wherein said superstrate is manufactured via coextrusion of two or more polymers to obtain said pre-existing curvature, which is determined from the different shrinkages of the polymers in the coextruded superstrate.

28. The method claimed in claim 24 wherein said superstrate is manufactured via liquid coating on an existing superstrate, wherein the curvature of the coated film is determined from the different shrinkages of said superstrate and said coating.
